(19) United States
(12) Patent Application Publication
(10) Pub. No.: US 2026/0003805 A1
(43) Pub. Date: Jan. 1, 2026

(54) DATA READOUT METHOD, CORRESPONDING CIRCUIT AND MEMORY DEVICE

(71) Applicant: STMICROELECTRONICS INTERNATIONAL N.V., Geneva (CH)

(72) Inventors: Santi Nunzio Antonino PAGANO, Catania (IT); Francesco LA ROSA, Rousset (FR); Francesca GRANDE, Siracusa (IT)

(21) Appl. No.: 19/236,158

(22) Filed: Jun. 12, 2025

(30) Foreign Application Priority Data
Jun. 26, 2024 (IT) 102024000014671

(51) Int. Cl. G06F 13/16; G06F 13/40

(52) U.S. Cl. CPC G06F 13/1668; G06F 13/4022

(57) ABSTRACT

A data readout method, corresponding circuit, and memory device are provided. In an example, plural memory banks in a memory device share a common data readout bus via respective sense amplifiers. Data are read from the memory banks in a sequence of readout operations wherein, during each readout operation, the sense amplifier of one of the memory banks takes control over the common data readout bus and data are read from that one memory bank via the sense amplifier taking control over the common data readout bus, while the sense amplifiers of the other memory banks are set to a high impedance state.

### CROSS REFERENCE TO RELATED APPLICATION(S)

This application claims the priority benefit of Italian patent application number 102024000014671, filed on Jun. 26, 2024, entitled “PROCEDIMENTO DI LETTURA DI DATI, CIRCUITO E DISPOSITIVO DI MEMORIA CORRISPONDENTI”, which is hereby incorporated by reference to the maximum extent allowable by law.

### Technical Field

The description relates to data readout buses in memory devices.

Aspects of the present description can be used, for instance, in managing multiple data buses in large memory arrays.

### Background

A multiplex approach can be resorted to in managing multiple data buses in large memory arrays.

For instance, in large flash memories the memory array can be partitioned in several banks; this facilitates reducing the bitline length to achieve fast reading performance and a lower consumption. Each bank is equipped with a respective sense amplifier (“page” or bank) that outputs the data being read and plural output data buses are multiplexed to obtain a single output data bus.

Multiplexing introduces a further delay in access time.

Moreover, issues may arise related to synchronizing the output data and the control signal of the multiplexing action to counter undesired spurious switching over the data bus resulting from multiplexing.

Resorting to multiplexing also has a certain impact on the occupation area. This is related to the provision of data bus routing (which may also cause congestion problems) and the logical gates involved (whose number increases with the number of memory banks).

### BRIEF SUMMARY

An object of one or more embodiments is to contribute in addressing the issues discussed in the foregoing.

According to one or more embodiments, such an object can be achieved via a method having the features set forth in the claims that follow.

One or more embodiments relate to a corresponding circuit. A sense amplifier configured to be coupled to a memory bank to read data therefrom may be exemplary of such a circuit.

One or more embodiments relate to a corresponding memory device.

In solutions as described herein the data outputs from plural memory banks are shared over a single common data bus without resorting to multiplexers.

In solutions as described herein, such an output data bus is retained by one sense bank only (the last one involved in reading, for instance); during a read operation, the bus is released (in a high-impedance, HiZ state) without being driven for a short time (few nanoseconds, for instance): due to its own capacitance, it is not discharged and no switching takes place on the bus during this time.

In solutions as described herein, when switching, a sense amplifier autonomously takes control of its net inside the bus without any delay; control of the bus takes place locally in the bank, within each sense amplifier.

Solutions as described herein effectively counter possible spurious commutations on the output bus and the associated extra consumption; no delay is added to access time and semiconductor (silicon) area is saved in so far as only one output data bus is used irrespective of the number of memory banks, while multiplexers are dispensed with.

### BRIEF DESCRIPTION OF THE DRAWINGS

One or more embodiments will now be described, by way of example only, with reference to the annexed figures, wherein:

FIG. 1 is a block diagram exemplary of a conventional approach in managing multiple data buses in a memory arrays;

FIG. 2 represents possible time behaviors (waveforms) of signals that may occur in an arrangement as illustrated in FIG. 1;

FIG. 3 is a block diagram exemplary of managing multiple data buses in a memory array according to solutions as described herein;

FIG. 4 is a circuit diagram exemplary of possible details of the arrangement of FIG. 3;

FIG. 5 represents possible time behaviors (waveforms) of signals that may occur in solutions as described herein;

FIG. 6 is a circuit diagram exemplary of possible further details of the arrangement of FIG. 3; and

FIG. 7 and FIG. 8 represent possible time behaviors (waveforms) of signals that may occur in solutions as described herein.

The figures are drawn to clearly illustrate the relevant aspects of the embodiments and are not necessarily drawn to scale.

The edges of features drawn in the figures do not necessarily indicate the termination of the extent of the feature.

### DETAILED DESCRIPTION

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for the sake of brevity.

Once more, for the sake of simplicity and ease of explanation, a same designation may be applied throughout this description to designate:
a certain node or line as well as a signal occurring at that node or line, and/or
a certain component (such as a capacitor, resistor or inductor of coil) as well as electrical parameters thereof.

When it is mentioned that an element is “connected to” or “coupled to” another element, it should be understood that still another element may be interposed therebetween, as well as that the element may be connected or coupled directly to another element. On the contrary, when it is mentioned that an element is “connected directly to” or “coupled directly to” another element, it should be understood that still another element is not interposed therebetween.

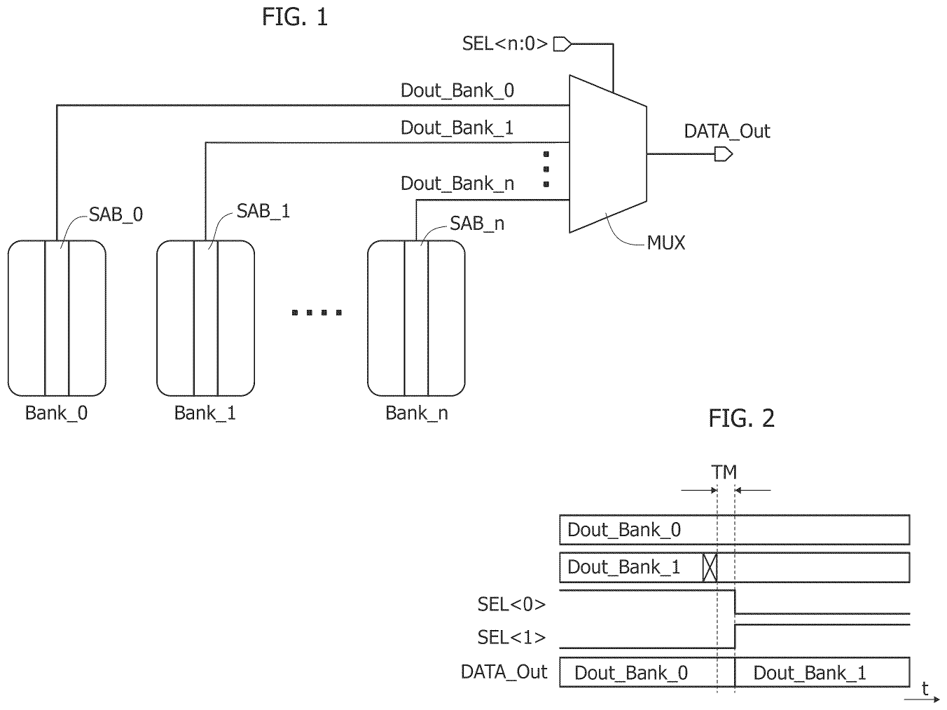

FIG. 1 is a block diagram exemplary of a conventional approach in managing multiple data buses Dout_Bank_0, Dout_Bank_1, . . . , Dout_Bank_n from respective memory banks Bank_0, Bank_1, . . . , Bank_n in a (large) memory array, such as a large flash memory, for instance.

Partitioning a memory array in several banks facilitates reducing the bitline length to achieve fast reading performance and a lower consumption.

The output buses Dout_Bank_0, Dout_Bank_1, . . . , Dout_Bank_n from sense amplifier banks SAB_0, SAB_1, . . . , SAB_n equipping the data banks Bank_0, Bank_1, . . . , Bank_n are applied to the inputs of a multiplexer MUX that produces, under the control of selection signal SEL<n:0> a single output data flow on an output bus DATA_Out.

Possible operation of such an arrangement is illustrated (in connection with the data buses Dout_Bank_0 and Dout_Bank_1 taken as examples) in the diagram of FIG. 2.

The diagram of FIG. 2 illustrates, against a common abscissa time scale t, possible time behaviors (waveforms) of (from top to bottom):
a data flow over the data bus Dout_Bank_0;
a data flow over the data bus Dout_Bank_1;
a signal SEL<0> that, when asserted to “1”, couples to the output bus DATA_Out the data bus Dout_Bank_0;
a signal SEL<1> that, when asserted to “1”, couples to the output bus DATA Out the data bus Dout_Bank_1; and
a resulting data flow over the output bus DATA_Out.

As visible in FIG. 2, a time margin TM is added between to avoid spurious commutation on the output bus DATA_Out.

This results in a delay added to access time and may also lead to issues related to the synchronization of output data with the control signal SEL<n:0> of the multiplexer MUX. Additionally, multiplexing has negative effects in term of occupation area related to the provision of data bus routing and the logical gates involved.

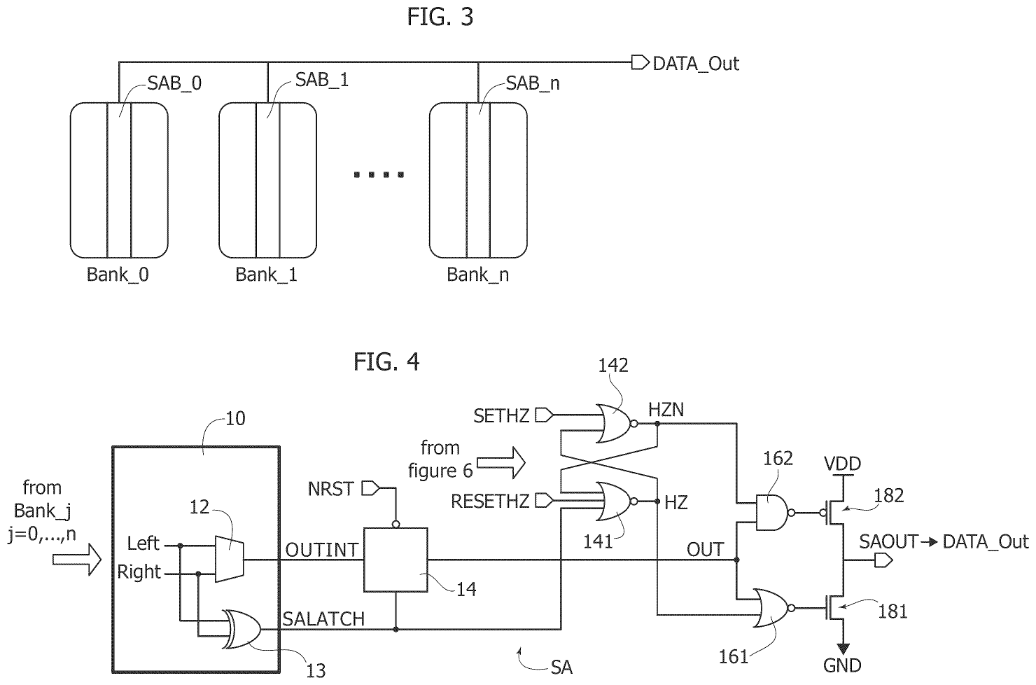

FIG. 3 is a general block diagram exemplary of an approach adopted in solutions as described herein. These are again intended to manage multiple data buses from respective memory banks Bank_0, Bank_1, . . . , Bank_n in a memory array.

A large flash memory can be again mentioned as a possible instance of such a memory array.

In solutions as illustrated in FIG. 3, the data outputs from the different banks Bank_0, Bank_1, . . . , Bank_n are (directly) shared over a single output data bus DATA_out without resorting to multiplexers such as the multiplexer MUX in FIG. 1.

In solutions as described herein, the output data_bus DATA_Out is intended to be retained by (only) one sense bank sense amplifier SAB_0, SAB_1, . . . , SAB_n at a time, for instance by the one involved in the latest reading operation.

During a read operation, the bus Data_Out is released to a high-impedance, HiZ state and is not driven for a short time (few nanoseconds, by way of non-limiting example). Due to its own capacitance, the bus is not discharged and no switching takes place thereon the bus during this time.

In solutions as described herein, whenever a sense amplifier SAB_0, SAB_1, . . . , SAB_n switches (becomes active), such sense amplifier takes autonomous control of an associated net in the bus Data_Out, without any delay.

In that way, a read operation in one bank (Bank_1, for instance) takes place with the other banks Bank_0, . . . , Bank_n (the banks different from Bank_1, in the exemplary case considered) in a high impedance (HiZ) state.

FIG. 4 is a circuit diagram exemplary of possible details of the arrangement of FIG. 3.

Essentially, FIG. 4 is a diagram exemplary of possible circuit architecture, designated SA as a whole, of any of the sense amplifiers SAB_0, SAB_1, . . . , SAB_n configure to be coupled to respective memory banks Bank_j, with j=1, . . . , n.

In the exemplary representation of FIG. 4, reference 10 indicates the core of the SA architecture, which is configured (in a manner known per se to those of skill in the art) in such a way that the commutation of the SA core 10 generates two signals:
OUTINT, which corresponds to the reading result—essentially the data that in FIG. 1 are conveyed over the buses Dout_Bank_0 to Dout_Bank_n, through a reference latch and a buffer circuit driven by high-impedance (HiZ) control signals (as further detailed in the following), and
SALATCH, which is a trigger of reading completion.

These signals can be obtained in a manner known per se to those of skill in the art.

For instance:
the signal OUTINT can be produced by a differential readout block 12 coupled to “Left” and “Right” bit lines in complementary memory sections in an associated memory block memory banks Bank_j, with j=1, . . . , n (not visible in FIG. 4), and
the signal SALATCH can be produced by via an EX-OR gate 13 coupled to the “Left” and “Right” bit lines.

The signals SETHZ and RESETHZ are produced (in the various memory banks Bank_0, Bank_1, . . . , Bank_n as detailed in connection with FIG. 6) to set and reset a high-impedance state based on combinations of the main signals (to manage the HiZ state of the lines from the banks Bank_0, Bank_1, . . . , Bank n in the power-on phase) and read control signals (to manage the reading)

Reference 14 in FIG. 4 indicates a latch block supplied with the signal OUTINT and configured to issue an output signal OUT.

As illustrated, the latch block 14 is sensitive to the signal SALATCH (trigger of reading completion) and to a (negated) NRST input which, in the case of a flash memory, can be used to reset and load a new application in flash.

In FIG. 4, references 141 and 142 indicate two NOR gates configured to produce a signal HZ to set a high impedance state and a signal NHZ to reset a high impedance state.

As illustrated in FIG. 4, the first NOR gate 141 has three inputs that receive:
the signal RESETHZ,
the signal SALATCH, and
the signal HZN (from the output of the second NOR gate 142, in a cross-coupling arrangement), respectively.

As illustrated in FIG. 4, the second NOR gate 142 has two inputs that receive:
the signal SETHZ, and
the signal HZ (from the output of the first NOR gate 141, in a cross-coupling arrangement), respectively.

In FIG. 4, references 161 and 162 indicate a NOR gate and a NAND gate configured to drive the control terminals (gates, in the case of field-effect transistors such as MOSFET transistors) of two electronic switches (MOSFET transistors, for instance) 181, 182 arranged with the current flow paths therethrough (source-drain, in the case of field-effect transistors such as MOSFET transistors) cascaded in series in a current flow line between a supply node VDD and ground GND.

As illustrated in FIG. 4, the NOR gate 161 has two inputs that receive:
the signal OUT from the latch 12, and
the signal HZ from the NOR gate 141, respectively.

As illustrated in FIG. 4, the NAND gate 162 has two inputs that receive:
the signal OUT from the latch 12, and
the signal HZN from the NOR gate 142, respectively.

An output node on the current flow line between the supply node VDD and ground GND between the two electronic switches 181, 182 provides an output signal SAOUT from the sense amplifier architecture SA of any of the sense amplifiers SAB_0, SAB_1, SAB_n to provide the output data flow DATA-Out.

The switches 181, 182 thus provide an output driver stages for the sense amplifier architecture SA of FIG. 4.

To summarize, sense amplifier architecture indicated as SA in FIG. 4 comprises:
a data readout stage (essentially the SA core 10 and the latch 14) configured to be coupled to a respective memory bank Bank_j (j=1, . . . , n) to read data OUTINT therefrom, and
an output stage including the electronic switches (MOSFET transistors, for instance) 181, 182 that are configured to be coupled (at the node SAOUT) to the common data readout bus DATA_Out to transfer to the common data readout bus DATA_Out the data OUTINT read from the respective memory bank via the readout stage 10, 14.

In sense amplifier architecture indicated as SA in FIG. 4 the logic gates 141, 142, 161, 162 provide impedance variation circuitry arranged between the readout stage 10, 14 and the output stage 181, 182, which such impedance variation circuitry configured to be switched (see the signals HNZ, HZ generated based on the signals RESETHZ and SETHZ) between:
a data transfer state, wherein the output stage 181, 182 has control over the common data readout bus DATA_Out and data OUTINT read from the respective memory bank Bank_j (j=0, . . . , n) via the readout stage 10, 14 are transferred to the common data readout bus DATA_Out during a data readout operation via the switches 181, 182 that are made selectively conductive, and
a high-impedance state (HiZ), wherein transfer of data from the readout stage 10, 14 to the common data readout bus DATA_Out is countered (in response to the switches 181, 182 being non-conductive) to disable data readout operations.

As illustrated in FIG. 4, the readout stage 10, 14 may advantageously comprise a latch signal generator (the EX-OR gate 13) configured to assert the signal SALATCH indicative of completion of a data readout operation during which data OUTINT read from the respective memory bank via the readout stage 10, 14 are transferred to the common data readout bus DATA_Out. As illustrated, the impedance variation circuitry (including the elements 141, 142, 161, 162) is coupled (at the NOR gate 141) to the latch signal generator and is thus configured to switch (via the signals NHZ and HZ) from the high-impedance state to the data transfer state in response to the signal indicative of completion of a data readout operation being asserted.

As illustrated in FIG. 4, the output stage may advantageously comprise a first electronic switch (the MOSFET transistor 181) and a second electronic switch (the MOSFET transistor 182) arranged with current flow paths therethrough (source-drain in the case of field-effect transistors such as MOSFET transistors) cascaded in series in a current flow line between a supply node VDD and ground GND. An output node SAOUT in such a current flow line intermediate the first electronic switch 181 and the second electronic switch 182 is coupled to the common data readout bus DATA Out.

As illustrated in FIG. 4, the first electronic switch 181 and the second electronic switch 182 can be selectively made conductive (in the data transfer state) and non-conductive in the high-impedance state (HiZ).

More specifically, as illustrated by way of example in FIG. 4, the first electronic switch 181 and the second electronic switch 182 have control terminals (gates, in the case of field-effect transistors such as MOSFET transistors) driven by the outputs of a first logic gate (the NOR gate 161) and a second logic gate (the NAND gate 162), wherein both the first logic gate 161 and the second logic gate 162 have a respective first input coupled to the readout stage 10, 14 to receive therefrom the data OUTINT read from the respective memory bank, Bank_j (j=0, . . . , n).

As illustrated by way of example in FIG. 4, the first logic gate 161 and the second logic gate 162 have a respective second input coupled to the gates 141, 142 configured to act as state control circuitry by generating a gating signal that has a first logic value (namely, NHZ) in the data transfer state and a second logic value (namely, HZ) in the high-impedance state (HiZ).

As illustrated by way of example in FIG. 4, the first logic gate 161 and the second logic gate 162 are configured to make the first electronic switch (the MOSFET transistor 181) and the second electronic switch (the MOSFET transistor 182) conductive and non-conductive in response to the gating signal having the first logic value NHZ or the second logic value HZ, respectively.

As illustrated by way of example in FIG. 4, the state control circuitry may comprise a first NOR gate 141 and a second NOR gate 142, wherein:
the first NOR gate 141 comprises inputs configured to receive a high-impedance reset signal RESETHZ and the output HZN from the second NOR gate 142; and
the second NOR gate 142 comprises inputs configured to receive a high-impedance set signal SETHZ and the output HZ from first NOR gate 141.

Advantageously, the first NOR gate 141 may also comprise an input configured to receive the signal SALATCH indicative of completion of a data readout operation.

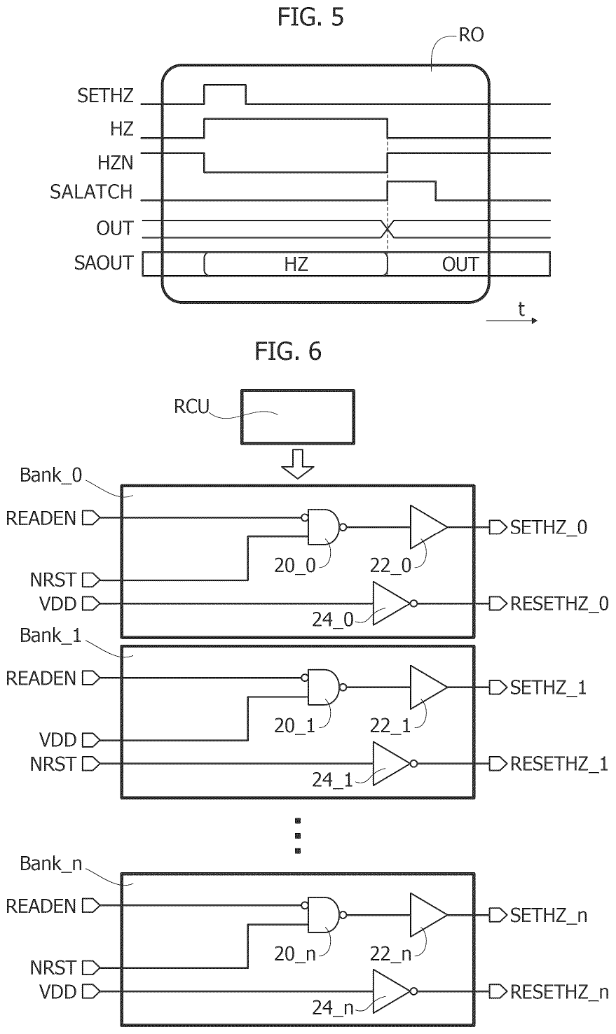

By way of example of possible operation of architecture as illustrated in FIG. 4, the diagram of FIG. 5 shows, against a common abscissa time scale t, possible time behaviors (waveforms) of signals involved in a read operation of data from a memory configured as illustrated in FIG. 3.

More specifically, the diagram of FIG. 5 shows possible time behaviors (waveforms) of (from top to bottom):
the signal SETHZ;
the signal HZ;
the signal HZN;
the signal SALATCH;
the signal OUT; and
the signal SAOUT.

FIG. 6 is a circuit diagram exemplary of circuitry configured to generate of respective signals SETHZ and RESETHZ for a plurality of memory banks Bank_0, Bank_1, Bank_n.

In FIG. 6, the signals SETHZ and RESETHZ for the memory bank Bank_0 are designated SETHZ_0 and RESETHZ_0, the signals SETHZ and RESETHZ for the memory bank Bank_1 are designated SETHZ_1 and RESETHZ_1 and so on until the signals SETHZ and RESETHZ for the memory bank Bank_n, which are designated SETHZ_n and RESETHZ_n.

These signals are intended to be applied to the inputs SETHZ and RESTHZ of respective sense amplifier banks for memory banks Bank_0, Bank_1, . . . , Bank_n.

These sense amplifier banks are assumed to be configured for all for the memory banks Bank_0, Bank_1, . . . , Bank_n according to a same architecture SA as illustrated by in FIG. 4: for that reason, such architecture is illustrated only once.

By way of contrast, the circuitry configured to generate the respective signals SETHZ and RESETHZ for a plurality of memory banks Bank_0, Bank_1, . . . , Bank_n is represented to include n+1 (otherwise identical) circuits, each intended to be associated to a respective one of the memory banks Bank_0, Bank_1, . . . , Bank_n.

In each circuit illustrated in FIG. 6 (with the exception of one of them, for instance the circuit associated with the bank Bank_1):
a NAND gate 20_0, . . . , 20_n has a first input receiving a binary complementary (0>>>1, 1>>>0) version of a read enable signal READEN (generated in a manner known per se to those skilled in the art) and a second input receiving the signal NRST;
a buffer stage 22_0, . . . , 22_n is configured to produce a signal SETHZ_0, . . . , SETHZ_n from the output of the NAND gate 20_0, . . . , 20_n; and
a logic inverter 24_0, . . . , 24_n is configured to produce the signal RESETHZ_0, . . . , RESETHZ_n from the signal VDD.

In the circuit associated with the bank Bank_1, the input signals NRST and VDD are “inverted” with respect to the circuits associated with the other banks. In the circuit associated with the bank Bank_1, the input of the inverter 24_1 is NRST and the inputs of the NAND gate 20_1 are READEN and VDD.

This is exemplary of a possibility of managing an initial condition at power on: one of the banks (the bank Bank_1, by way of example) drives the Data Out bus until first reading operation.

As illustrated in FIG. 6, a readout control unit RCU can be configured (in a manner known per se to those of skill in the art) to generate and forward towards the memory banks Bank_0, Bank_1, . . . , Bank_n signals READEN, NRST and VDD with values as discussed previously that result in signals SETHZ_0, RESETHZ_0, SETHZ_1, RESETHZ_1, . . . , SETHZ_n, RESETHZ_n (intended to be applied to the logic gates 141, 142 in architecture SA as illustrated in FIG. 4) such that during each readout operation:
the sense amplifier of one of the memory banks Bank_0, Bank_1, . . . , Bank_n takes control over the common data readout bus DATA_Out and data (OUTINT in FIG. 4) are read from that one of the memory banks Bank_0, Bank_1, . . . , Bank_n via the sense amplifier that has taken control over the common data readout bus DATA_Out; and
the sense amplifiers of the other memory banks Bank_0, Bank_1, . . . , Bank_n (different from the one which has control over the common data readout bus DATA_Out are set to a high impedance state (HiZ), so that the common data readout bus DATA_Out is decoupled from the respective readout stages 10 in the sense amplifiers of these “other” memory banks.

FIG. 6 (read in combination with FIGS. 3 and 4) is thus exemplary of a possible structure of a memory device comprising:
a plurality of memory banks Bank_0, Bank_1, . . . , Bank_n,
a plurality of sense amplifiers SAB_0, SAB_1, . . . , SAB_n wherein each sense amplifier includes architecture SA as exemplified in FIG. 4 and including a readout stage 10, 14 coupled to a respective one of the memory banks Bank_0, Bank_1, . . . , Bank_n to facilitate reading data OUTINT therefrom, and
a readout control unit RCU coupled to the plurality of sense amplifiers SAB_0, SAB_1, . . . , SAB_n and configured to selectively switch the impedance variation circuitry therein (the logic gates 141, 142, 161, 162) between the data transfer state and the high-impedance state (Hiz).

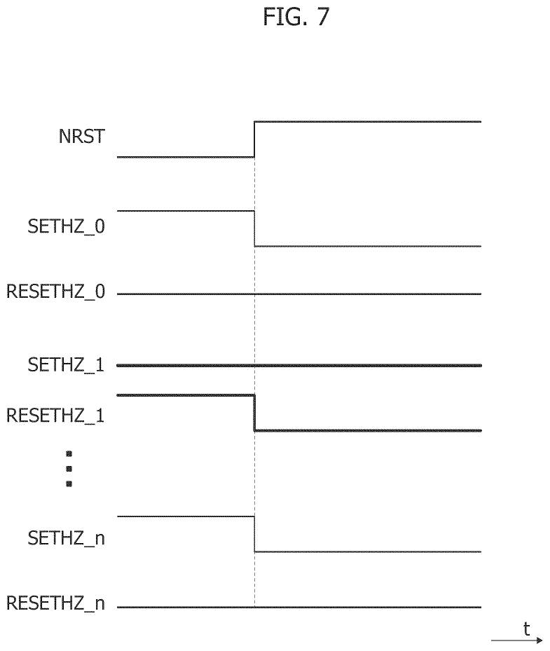

By way of example of possible operation of solutions as described herein, the diagram of FIG. 7 shows, against a common abscissa time scale t, possible time behaviors (waveforms) of signals involved in circuit power on in a condition where the bank Bank_1 drives the output bus DATA_Out until a first read operation takes place.

That is, the diagram of FIG. 7 is exemplary of a sequence of readout operations being started from a power on condition of the respective sense amplifiers SAB_0, SAB_1, . . . , SAB_n of the memory banks Bank_0, Bank_1, . . . , Bank_n wherein control over the common data readout bus DATA_Out is allotted by default (RESETHZ_1) to a selected one of the sense amplifiers (namely SAB_1, associated with the memory bank Bank_1) of the memory banks Bank_0, Bank_1, . . . , Bank_n.

More specifically, the diagram of FIG. 7 shows possible time behaviors (waveforms) of (from top to bottom):
the signal NRST;
the signal SETHZ_0 for the bank Bank_0;
the signal RESETHZ_0 for the bank Bank_0;
the signal SETHZ_1 for the bank Bank_1;
the signal RESETHZ_1 for the bank Bank_1;
the signal SETHZ_n for the bank Bank_n;
the signal RESETHZ_0 for the bank Bank_n.

These two last signals are identical to the signals SETHZ_0 and RESETHZ_0 for the bank Bank_0: this is exemplary of a condition where (only) the signals SETHZ_1 and RESETHZ_1 for the bank Bank_1 have a different behavior from the signals the signals SETHZ_j and RESETHZ_j for all the other banks in the memory array.

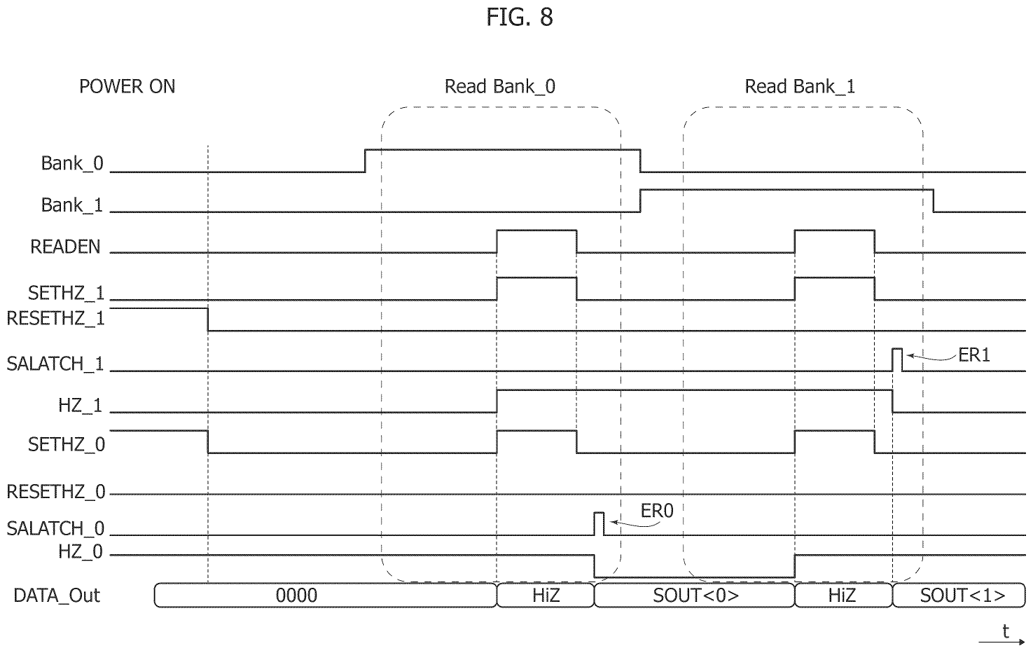

By way of further example of possible operation of solutions as described herein, the diagram of FIG. 8 shows, against a common abscissa time scale t, possible time behaviors (waveforms) of signals involved in operation including, after POWER ON a read operation Read Bank_0 from, by way of non-limiting example, the bank Bank_0 followed by another read operation Read Bank_1 from, likewise by way of non-limiting example, the bank Bank_1.

More specifically, the diagram of FIG. 8 shows possible time behaviors (waveforms) of (from top to bottom):
the data Read Bank_0 read from the bank Bank_ 0;
the data Read Bank_1 read from the bank Bank_1;
a read enable signal READEN that, when asserted (to “1”, for instance) results in high impedance state HiZ (see also the lowermost curve in FIG. 8);
the signal SETHZ_1 for the bank Bank_1;
the signal RESETHZ_1 for the bank Bank_1;
the signal SALATCH_1 for the bank Bank_1;
the signal HZ_1 for the bank Bank_1;
the signal SETHZ_0 for the bank Bank_0;
the signal RESETHZ_0 for the bank Bank_0;
the signal SALATCH_0 for the bank Bank_0;
the signal HZ_0 for the bank Bank_0; and
the (single) output signal DATA_Out.

This last signal includes, after an initial string of zeroes 0000 after power on:
a first high-impedance condition HiZ,
an output data string SOUT<0> (the data read from the bank Bank_0) timed by a pulse ER0 in the signal SALATCH_0 marking the end of reading from the bank Bank_0,
a further high-impedance condition HiZ,
an output data string SOUT<1> (the data read from the bank Bank_1) timed by a pulse ER1 in the signal SALATCH_1 marking the end of reading from the bank Bank_1.

The diagram of FIG. 8 is thus further exemplary of operation wherein the sense amplifier SAB_1 of the memory bank Bank_1 from which data are read during the last readout operation in a sequence of readout operations retains control over the common data readout bus DATA_Out over a short time interval (few nanoseconds, for instance) with switching of the common data readout bus DATA Out disabled during that time interval: due to its own capacitance, even without being driven for a short time, the bus DATA_Out is not discharged with no switching taking place thereon.

The diagram of FIG. 8 evidences advantages of solutions as described herein such as:
spurious commutations of the output bus DATA_Out avoided;
no extra consumption;
a high-impedance (HiZ) state released in response to an architecture SA becoming ready at the end of a reading operation;
a single data bus DATA_Out irrespective of the number of memory banks involved;
multiplexers dispensed with.

Without prejudice to the underlying principles, the details and embodiments may vary, even significantly, with respect to what has been described by way of example only, without departing from the extent of protection.

The extent of protection is determined by the annexed claims.

1. A method, comprising:
coupling a plurality of memory banks to a common data readout bus via respective sense amplifiers,
reading data from memory banks in the plurality of memory banks in a sequence of readout operations wherein, during each readout operation:
the sense amplifier of one of the memory banks in the plurality of memory banks takes control over the common data readout bus and data are read from the one of the memory banks in the plurality of memory banks via the sense amplifier taking control over the common data readout bus, and
the sense amplifiers of other memory banks in the plurality of memory banks different from the one of the memory banks in the plurality of memory banks are set to a high impedance state.

2. The method of claim 1, wherein the sense amplifier of a memory bank from which data are read during a last readout operation in the sequence of readout operations retains control over the common data readout bus over a time interval, with switching of the common data readout bus disabled during the time interval.

3. The method of claim 1, comprising starting the sequence of readout operations from a power on condition of the respective sense amplifiers of the memory banks in the plurality of memory banks wherein control over the common data readout bus is allotted by default to a selected one of the sense amplifiers of the memory banks in the plurality of memory banks.

4. A sense amplifier comprising:
a readout stage configured to be coupled to a respective memory bank in a plurality of memory banks to read data from respective memory bank;
an output stage configured to be coupled to a common data readout bus to transfer to the common data readout bus data read from the respective memory bank via the readout stage,
impedance variation circuitry between the readout stage and the output stage, the impedance variation circuitry configured to be switched between:
a data transfer state, wherein the output stage has control over the common data readout bus and data read from the respective memory bank via the readout stage are transferred to the common data readout bus during a data readout operation; and
a high-impedance state, wherein transfer of data from the readout stage to the common data readout bus is countered to disable data readout operations.

5. The sense amplifier of claim 4, wherein the readout stage comprises a latch signal generator configured to assert a signal indicative of completion of a data readout operation wherein data read from the respective memory bank via the readout stage are transferred to the common data readout bus; and
the impedance variation circuitry is coupled to the latch signal generator in the readout stage and is configured to switch from the data transfer state to the high-impedance state in response to the signal indicative of completion of a data readout operation being asserted.

6. The sense amplifier of claim 4, wherein the output stage comprises a first electronic switch and a second electronic switch arranged with current flow paths therethrough cascaded in a current flow line between a supply node and ground with an output node in the current flow line intermediate the first electronic switch and the second electronic switch coupled to the common data readout bus, the first electronic switch and the second electronic switch configured to be made conductive in the data transfer state and non-conductive in the high-impedance state.

7. The sense amplifier of claim 6, wherein:
the first electronic switch and the second electronic switch have control terminals driven by the outputs of a first logic gate and a second logic gate, wherein both the first logic gate and the second logic gate have a respective first input coupled to the readout stage to receive therefrom data read from the respective memory bank,
the first logic gate and the second logic gate have a respective second input coupled to state control circuitry configured to generate a gating signal having a first logic value in the data transfer state and a second logic value in the high-impedance state, wherein the first logic gate and the second logic gate are configured to make the first electronic switch and the second electronic switch conductive and non-conductive in response to the gating signal having the first logic value or the second logic value, respectively.

8. The sense amplifier of claim 7, wherein the first logic gate and the second logic gate comprise a NAND gate and a NOR gate, respectively.

9. The sense amplifier of claim 7, wherein the state control circuitry comprise a first NOR gate and a second NOR gate, wherein:
the first NOR gate comprises inputs configured to receive a high-impedance reset signal and the output from the second NOR gate; and
the second NOR gate comprises inputs configured to receive a high-impedance set signal and the output from first NOR gate.

10. The sense amplifier of claim 5, wherein the first NOR gate comprises an input configured to receive the signal indicative of completion of a data readout operation.

11. A memory device, comprising:
a plurality of memory banks;
a plurality of sense amplifiers according to claim 4, wherein each sense amplifier includes a readout stage coupled to a respective memory bank in plurality of memory banks to facilitate reading data therefrom; and
a readout control unit coupled to the plurality of sense amplifiers and configured to selectively switch the impedance variation circuitry therein between the data transfer state and the high-impedance state.
